(19) United States
(12) Patent Application Publication
(10) Pub. No.: US 2011/0294237 A1
(43) Pub. Date: Dec. 1, 2011

(54) PACKAGING METHOD OF SEMICONDUCTOR DEVICE

(75) Inventor: Wen-Hsiung CHANG, Hsinchu City (TW)

(73) Assignee: MOS Art Pack Corporation

(21) Appl. No.: 12/788,360

(22) Filed: May 27, 2010

(51) Int. Cl. H01L 21/66

(52) U.S. Cl. 438/15; 257/E21.529

(57) ABSTRACT

In a packaging method of semiconductor device, firstly, a wafer including a number of dies is provided. The wafer has an active surface and a back surface. The active surface adheres to a carrier. Subsequently, a number of openings are formed in each of the dies. Then, an insulating layer is formed on the back surface and on the side walls of the openings. A metal layer is formed to cover the insulating layer and the bottoms of the openings. A pattern protective layer is formed to cover the metal layer and to expose the metal layer outside the openings. Afterwards, the carrier is removed and the wafer is sawed. Later, a transparent substrate having a number of package units is provided. A spacer is formed at peripheral of each of the package units. A number of good dies are choose from the dies and disposed on the spacer.

### BACKGROUND

1. Field of the Invention

The present invention relates to a packaging method of a semiconductor device, and particularly to a packaging method of an image sensor that is capable of improving package quality of the image sensor.

2. Description of the Related Art

Image sensor is used for transforming optical signals into electrical signals, and has been mainly used in a variety of digital image electronic devices. Nowadays, the digital image electronic devices have the stream of light, thick, small, high speed and performance. In the process of manufacturing the digital image electronic devices, what is needed to be improved continuously is, for example, to cut down the package cost, to increase the component density and to reduce the component sizes. Thus, the conventional packaging method has not satisfied the demand of present digital image electronic devices.

Generally, the image sensor is packaged by a wafer level package (WLP). The wafer level package refers to the technology of packaging an integrated circuit at wafer level, instead of the traditional process of assembling the package of each individual unit after wafer dicing. In the process of the wafer level package, at first, a previous process is performed, which includes fabricating components on a surface of a wafer, disposing a conductive pattern on the surface of the wafer, and so on. Subsequently, an after process is performed, which includes packaging the whole wafer, testing the whole wafer, and so on. Afterwards, a wafer saw step is performed so as to forming a number of resulting chip packages. In the process of the wafer level package, the steps of wire bonding and filling adhesive are not necessary yet. Therefore, the resulting chip package is practically of the same size as the die.

However, because the wafer level package is base on a whole wafer to process the package, the quality of the die is not considered. Particularly, when the wafer has a poor quality, the quality of the resulting chip package will be affected. In other words, although some dies with poor quality have been found in the process of the wafer level package, the after process such as packaging is still performed. As a result, the material is wasted and the production cost is increased.

Therefore, what is needed is a packaging method of a semiconductor device to overcome the above disadvantages.

### BRIEF SUMMARY

The present invention provides a packaging method of semiconductor device that is capable of improving the quality of the resulting package. The package method can use apparatus with different sizes so as to reduce the cost.

To achieve the above-mentioned advantages, the present invention provides a packaging method of semiconductor device. The packaging method of semiconductor device includes the following steps. A wafer including a number of dies is provided. The wafer has an active surface and a back surface opposite to the active surface. The active surface of the wafer adheres to a carrier. Subsequently, a number of openings through the active surface and the back surface of the wafer are formed in each of the dies. Then, an insulating layer is formed on the back surface of the wafer and on the side walls of the openings. A metal layer is formed to cover the insulating layer and the bottoms of the openings. A pattern protective layer is formed to cover the metal layer and to expose the portions of the metal layer outside the openings of each of the die. Afterwards, the carrier is removed and the wafer is sawed so as to separate the dies. Later, a transparent substrate having a number of package units is provided. A spacer is formed at peripheral of each of the package units. A number of good dies are choose from the dies and are disposed on the spacer of each of the package units.

In one embodiment provided by the present invention, the packaging method of semiconductor device further includes a wafer thinning step before the openings are formed.

In one embodiment provided by the present invention, the packaging method of semiconductor device further includes a step of testing known good die before the good dies are choose from the dies.

In one embodiment provided by the present invention, the active surface and the carrier adhere to each other by an adhesive layer disposed between the active surface and the carrier. A material of the adhesive layer is a removable adhesive material.

In one embodiment provided by the present invention, the wafer is a semiconductor wafer comprising a plurality of image sensing components or micro electro mechanical systems.

In one embodiment provided by the present invention, the pattern protective layer extends into the openings, and an interspace is formed between the pattern protective layer and the metal layer on the bottom of the corresponding opening. In one embodiment provided by the present invention, the openings are filled with the pattern protective layer.

In one embodiment provided by the present invention, the process of forming the insulating layer includes the steps of: depositing a layer of an insulating material; and removing the insulating material to remove the portions of the insulating material corresponding to the openings so as to expose the bottoms of the openings.

In one embodiment provided by the present invention, after the good dies of the dies are disposed on the spacer of each of the package units, the packaging method of semiconductor device further includes forming a conductive bump on the exposed metal layer in each of the package units so as to electrically connect the good dies to the transparent substrate; and sawing the transparent substrate so as to separate the package units.

In the packaging method of the present invention, after the through silica vias are formed, the wafer is sawed. Before packaging, the wafer is tested to choose the good dies. Therefore, the quality of the resulting package can be improved. Additionally, because the packaging method of the present invention is not base on a whole wafer to process the package, it is not necessary to use an apparatus having a packaging size identical to the size the wafer. The method can use a variety of apparatuses with different packaging sizes to package the wafer.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1A to FIG. 1G are schematic flow charts of a packaging method of semiconductor device in accordance with an embodiment of the present invention.

### DETAILED DESCRIPTION

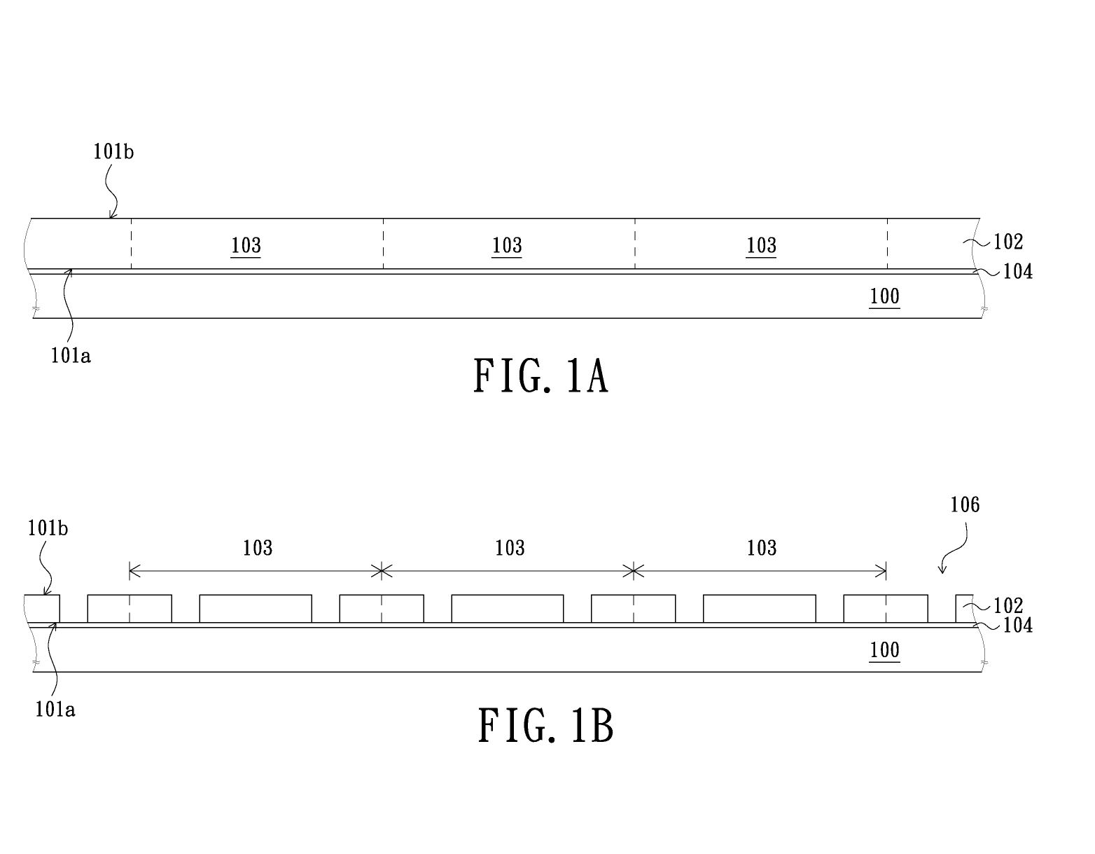

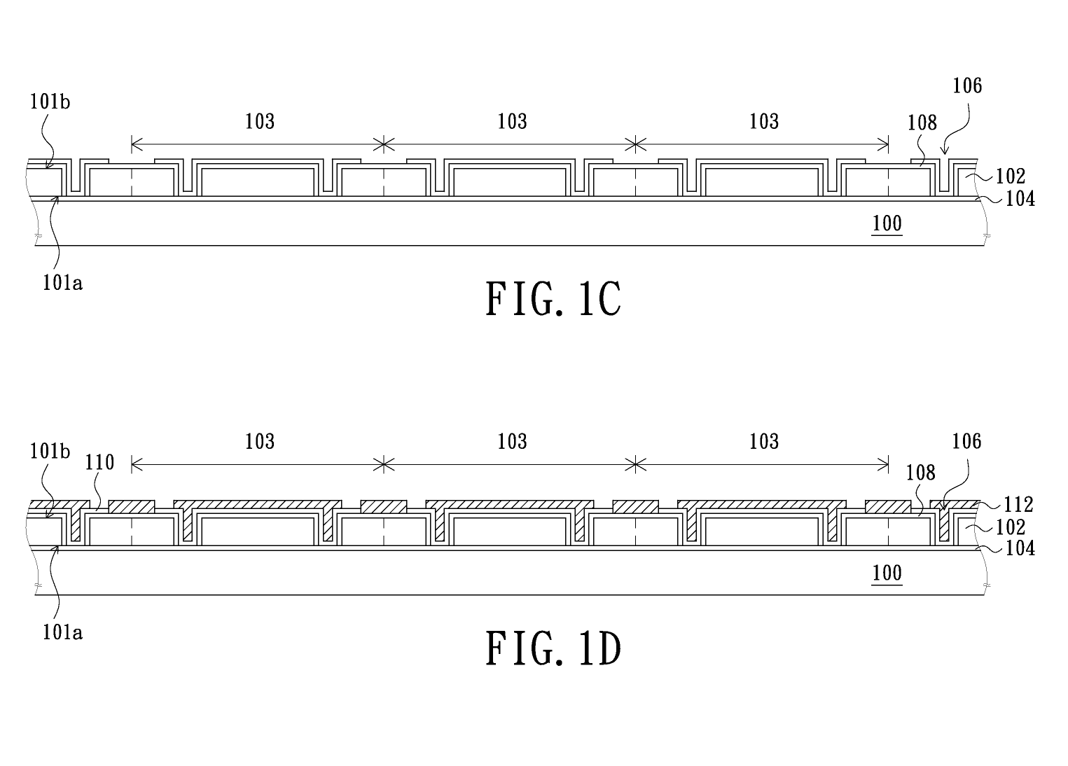

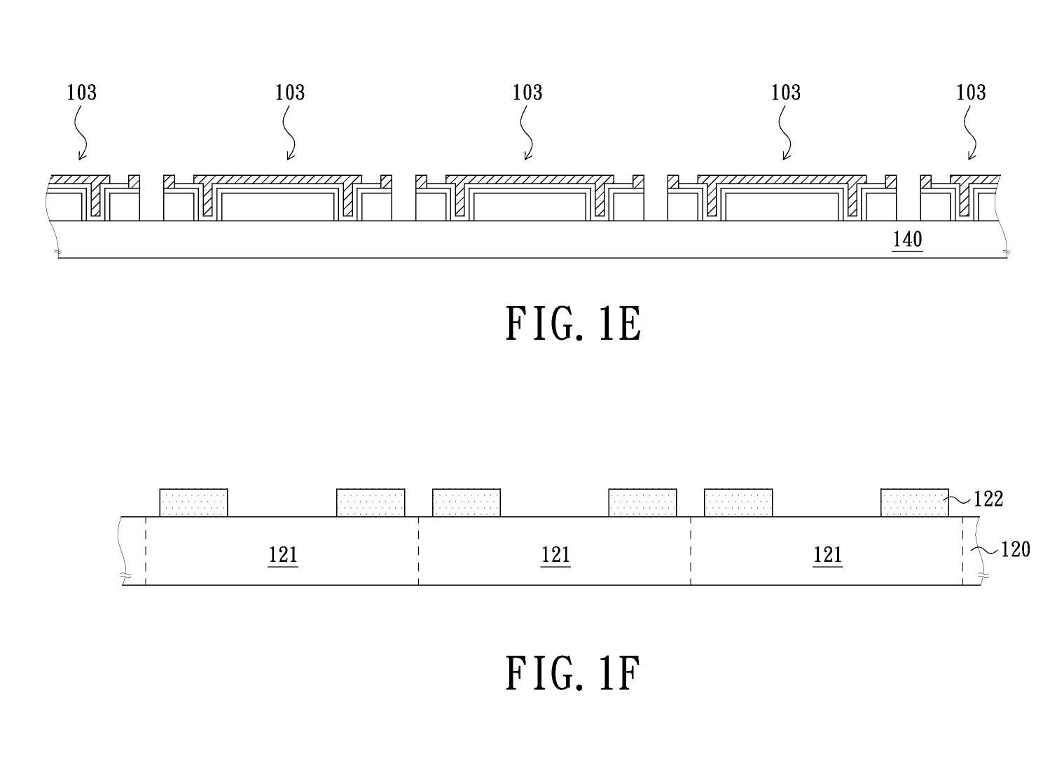

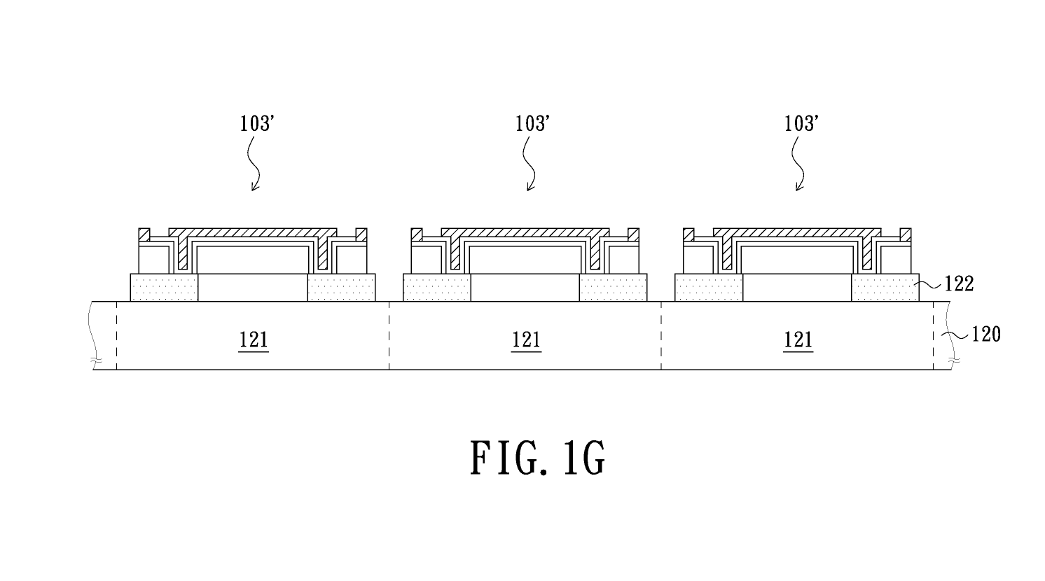

FIG. 1A to FIG. 1G are schematic flow charts of a packaging method of semiconductor device in accordance with an embodiment of the present invention.

Referring to FIG. 1A, a wafer 102 is provided. The wafer 102 is, for example, a semiconductor wafer including a number of image sensing components or micro electro mechanical systems (MEMS). The wafer 102 has an active surface 101a and a back surface 101b opposite to the active surface 101a. The wafer 102 is composed of a number of dies 103. The dies 103 are unseparated.

Still referring to FIG. 1A, a carrier 100 adheres to the active surface 101a of the wafer 102. In the present embodiment, the carrier 100 is made of a material, for example, silicon or glass. An adhesive layer 104 is disposed between the carrier 100 and the active surface 101a of the wafer 102 so that carrier 100 and the active surface 101a of the wafer 102 adhere to each other. The adhesive layer 104 can be made of a removable adhesive material, for example, epoxy and other similar polymers.

Subsequently, referring to FIG. 1B, a number of openings 106 are formed in each of the dies 103 of the wafer 102. The openings 106 penetrate the wafer 102. That is, the openings 106 are through the active surface 101a and the back surface 101b and are used as through silicon vias. For example, the openings 106 are formed by a reactive ion etching (RIE) method, or a laser drilling method. It is noted that the openings 106 can be formed by a wet etching method.

In the present embodiment, before the openings 106 are formed, a wafer thinning step can be selectively performed. Thus, the wafer 102 can be thinned to a suitable thickness. The wafer 102 can be thinned using a method selected from a group consisting of etching, milling, grinding and polishing.

Afterwards, referring to FIG. 1C, an insulating layer 108 is formed on the back surface 101b and the side walls of the openings 106. The insulating layer 108 is made of a material, for example, silicon oxide, silicon nitride, or other suitable insulating materials. A method of forming the insulating layer 108 includes the following steps. At first, a layer of an insulating material (not shown) is deposited on the back surface 101b of the wafer 102 and in the openings 106 using a depositing method. Then, an removing step is performed so that the portions of the insulating material corresponding to the openings 106 are removed so as to expose the bottoms of the openings 106.

Still referring to FIG. 1C, a metal layer 110 is filled into the openings 106 so as to form through silicon vias. In detail, the metal layer 110 is formed on the back surface 101b of the wafer 102 to cover the insulating layer 108, and extends into the openings 106 to cover the bottoms of the openings 106. A material of the metal layer 110 is, for example, copper, gold, aluminum, tungsten or an alloy of copper, gold, aluminum and tungsten. The metal layer 110 is formed using a depositing method.

Then, referring to FIG. 1D, a pattern protective layer 112 is formed to protect the metal layer 110. The portions of the metal layer 110 outside the openings 106 and on the back surface 101b of each of the dies 103 are exposed from the pattern protective layer 112. The pattern protective layer 112 is made of, for example, an electrical insulating material. A method of forming the pattern protective layer 112 includes the following steps. At first, a protective material (not shown) is deposited on the back surface 101b of the wafer 102 using a depositing method. Then, a patterning step is performed so that parts of the protective material are removed to expose the portion of the metal layer 110 therefrom, thereby patterning the protective material to form the pattern protective layer 112.

In the present embodiment, during the depositing process, the protective material will be filled into the openings 106. That is, the pattern protective layer 112 is partially located in the openings 106. An interspace is formed between the pattern protective layer 112 in the opening 106 and the metal layer 110 at the bottom of the corresponding opening 106. In another embodiment, the openings 106 can be filled with the pattern protective layer 112 (not shown). No interspace is formed between the pattern protective layer 112 in the opening 106 and the metal layer 110 at the bottom of the corresponding opening 106.

Referring to FIG. 1E, the carrier 100 and the adhesive layer 104 are removed so that the active surface 101a of the wafer 102 is exposed. Then, the wafer 102 is sawed so as to separate the dies 103. A method of sawing the wafer 102 for example includes the following steps. At first, the wafer 102 is attached to a sawing adhesive tape 140. Subsequently, the wafer 102 is adhered to the sawing adhesive tape 140 by a sawing frame (not shown). Afterwards, a wafer sawing step is performed so that the wafer 102 is sawed into the dies 103 having a specific size.

Referring to FIG. 1F, a transparent substrate 120, for example, a glass substrate, is provided. The transparent substrate 120 includes a number of package units 121. A spacer 122 is formed at peripheral of each of the package units 121 of the transparent substrate 120. The spacer 122 is configured for supporting the dies 103 on the transparent substrate 120 and forming a gap between components in the dies 103 and the transparent substrate 120. The spacer 122 is made of a dielectric material such as silicon oxide or a photoresist material. The spacer 122 is formed using a method selected from a group consisting of coating, exposing, etching, printing and dispensing.

Referring to FIG. 1G, a number of good dies 103′ are choose from the dies 103. Each of the good dies 103′ are respectively disposed on the spacers 122 of the package units 121 of the transparent substrate 120. Thus, a wafer redistribute structure is formed. As mentioned above, before the good dies 103′ are choose from the dies 103, a step of testing known good die (KGD) can be performed so as to know the good dies in the dies 103.

In the packaging method of the present invention, after the through silica vias are formed, the wafer is sawed and tested to choose the good dies at once. Therefore, in the after processes, only the good dies are choose to be packaged. Thus, a wafer with poor quality will not affect the quality of the resulting packages.

After the good dies 103′ are disposed on the spacers 122 of the transparent substrate 120, a conductive bump can be formed on the exposed metal layer 110 of the good die 103′ in each of the package units. The conductive bump is configured for electrically connecting the good dies 103′ to the transparent substrate 120. Then, the transparent substrate 120 can be sawed so that the package units 121 are separated to form a number of individual packages. The steps of forming the conductive bump and sawing the substrate are known by the skilled in the art, and are not described here.

In addition, because the package method of the present invention is not base on a whole wafer to process the package, it is not necessary to use an apparatus having a packaging size identical to the size the wafer. In other words, the packaging method is not limited by the size of the wafer, and the method can use a variety of apparatuses with different packaging sizes to package the wafer.

In summary, the present invention has at least the following advantageousness:

1. The quality of the resulting package can be improved, the material can be saved, and the package cost can be reduced.

2. The method can use a variety of apparatuses with different packaging sizes to package the wafer, thereby enhancing package efficiency.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A packaging method of a semiconductor device, comprising:
providing a wafer comprising a plurality of dies, the wafer having an active surface and a back surface opposite to the active surface, the active surface of the wafer adhering to a carrier;
forming a plurality of openings through the active surface and the back surface of the wafer in each of the dies;
forming an insulating layer on the back surface of the wafer and on the side walls of the openings;
forming a metal layer to cover the insulating layer and the bottoms of the openings;
forming a pattern protective layer to cover the metal layer and to expose the portions of the metal layer outside the openings of each of the die;
removing the carrier and sawing the wafer so as to separate the dies;
providing a transparent substrate having a plurality of package units, a spacer being formed at peripheral of each of the package units; and
choosing a plurality of good dies from the dies and disposing the good dies on the spacer of each of the package units.

2. The packaging method as claimed in claim 1, further comprising a wafer thinning step before the openings are formed.

3. The packaging method as claimed in claim 1, further comprising a step of testing known good die before the good dies are choose from the dies.

4. The packaging method as claimed in claim 1, wherein the active surface and the carrier adhere to each other by an adhesive layer disposed between the active surface and the carrier.

5. The packaging method as claimed in claim 5, a material of the adhesive layer is a removable adhesive material.

6. The packaging method as claimed in claim 1, wherein the wafer is a semiconductor wafer comprising a plurality of image sensing components or micro electro mechanical systems.

7. The packaging method as claimed in claim 1, wherein the pattern protective layer extends into the openings, and an interspace is formed between the pattern protective layer and the metal layer on the bottom of the corresponding opening.

8. The packaging method as claimed in claim 1, wherein the openings are filled with the pattern protective layer.

9. The packaging method as claimed in claim 1, wherein the process of forming insulating layer comprises the steps of:
depositing a layer of an insulating material; and
removing the insulating material to remove the portions of the insulating material corresponding to the openings so as to expose the bottoms of the openings.

10. The packaging method as claimed in claim 1, after the good dies of the dies are disposed on the spacer of each of the package units, further comprising:
forming a conductive bump on the exposed metal layer in each of the package units so as to electrically connect the good dies to the transparent substrate; and
sawing the transparent substrate so as to separate the package units.
